(19) United States
(12) Patent Application Publication
(10) Pub. No.: US 2012/0231294 A1
(43) Pub. Date: Sep. 13, 2012

(54) HOUSING FOR ELECTRONIC DEVICE AND METHOD FOR MANUFACTURING

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); SHUN-MAO LIN, Shenzhen City (CN)

(73) Assignees: HON HAI PRECISION INDUSTRY CO., LTD., Tu-Cheng (TW); HONG FU JIN PRECISION INDUSTRY (SHENZHEN) CO., LTD., Shenzhen City (CN)

(21) Appl. No.: 13/226,653

(22) Filed: Sep. 7, 2011

(30) Foreign Application Priority Data
Mar. 8, 2011 (CN) 201110054732.5

(51) Int. Cl. B32B 15/01; C23C 14/16; C23C 14/35

(52) U.S. Cl. 428/660; 428/615; 204/192.15

(57) ABSTRACT

A housing for an electronic device is described. The housing includes a substrate made of metal and an amorphous alloy film formed on the substrate. The bonding layer is a nickel-chromium alloy layer. The amorphous alloy film consists of an amorphous alloy having a super-cooled liquid region of 10 K or more. The amorphous alloy film defines a pattern on an outer surface thereof. The pattern is defined by recesses or protrusions formed on the outer surface. A method for making the housing is also described.

### BACKGROUND

1. Technical Field

The present disclosure generally relates to a housing for an electronic device and a method for making the housing.

2. Description of Related Art

Due to having many good properties such as high hardness, high abrasion resistance, and good chemical durability, nitride, carbide, and carbonitride of transition metals are coated on articles, such as housings for electronic devices and glasses frames to prolong the service life of the articles. However, coatings made of such compounds are usually composed of columnar crystals and have large spaces between the crystal grains. Thus, the erosion resistance of the coatings can be reduced. Furthermore, the coatings made of such compounds are hard to be processed by heat or machining, thereby it is hard to form tactility features protective patterns on these coatings.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings like reference numerals designate corresponding parts throughout the several views.

FIG. 1 is a cross-sectional view of an exemplary embodiment of a housing.

FIG. 2 is a block diagram of a process for the making the present housing according to an exemplary embodiment.

FIG. 3 is a schematic view of a magnetron sputtering device used for making the exemplary housing shown in FIG. 1.

### DETAILED DESCRIPTION

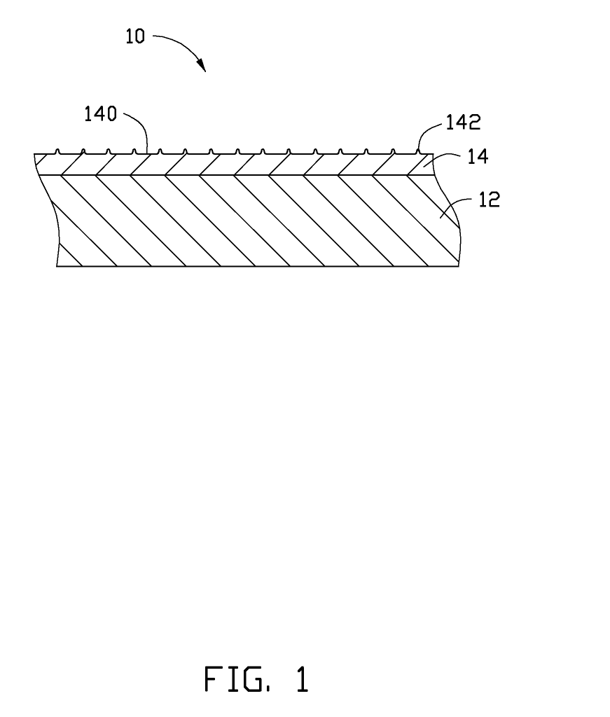

FIG. 1 shows a housing 10 for an electronic device according to an exemplary embodiment. The housing 10 includes a substrate 12 and an amorphous alloy film 14 formed on a surface of the substrate 12.

The substrate 12 is made of metal, such as stainless steel, magnesium alloy, aluminum alloy, titanium, or titanium alloy.

The amorphous alloy film 14 consists of an amorphous alloy, which has a super-cooled liquid region (ΔT) of 10 Kelvin (K) or larger. The term “super-cooled liquid region” is defined as the difference between the onset temperature of glass transition (Tg) and the onset temperature of crystallization (Tx) of an alloy. The value of ΔT is a measure of the amorphous phase-forming ability of the alloy. The amorphous alloy may be one selected from the group consisting of zirconium-based amorphous alloy, copper-based amorphous alloy, and titanium-based amorphous alloy. The zirconium-based amorphous alloy may have a composition represented by the formula Zr_{54%-65%}Al_{10%-20%}Co_{18%-28%} or Zr_{50%-70%}Al_{18%-12%}Ni_{10%-20%}Cu_{10%-20%}. The copper-based amorphous alloy may have a composition represented by one of the formulas Cu_{50%-65%}Zr_{40%-45%}Al_{3%-5%}, Cu_{58%-65%}Zr_{28%-32%}Ti_{8%-12%}, and Cu_{58%-65%} Hf_{23%-27%}Ti_{8%-12%}. The titanium-based amorphous alloy may have a composition represented by the formula Ti_{50%}Ni_{15%-20%}Cu_{24%-33%}Sn_{2%-6%}. Each of the subscript numerical values in the foregoing and following formulas indicates the weight percentage of a corresponding element within the alloy.

The amorphous alloy film 14 defines a three-dimensional pattern 142 on an outer surface 140 of the amorphous alloy film 14. The pattern 142 may be defined by recesses or protrusions formed on the outer surface 140. Thus, the pattern 142 is three-dimensional and gives users a three-dimensional tactility. In this exemplary embodiment, the pattern 142 is defined by a plurality of strips protruding from the outer surface 140.

The amorphous alloy film 14 may be formed by vacuum deposition, such as magnetron sputtering or arc ion plating. The thickness of the amorphous alloy film 14 may be about 0.5 μm-3 μm. The pattern 142 may be formed by hot-pressing the amorphous alloy film 14 with a mold.

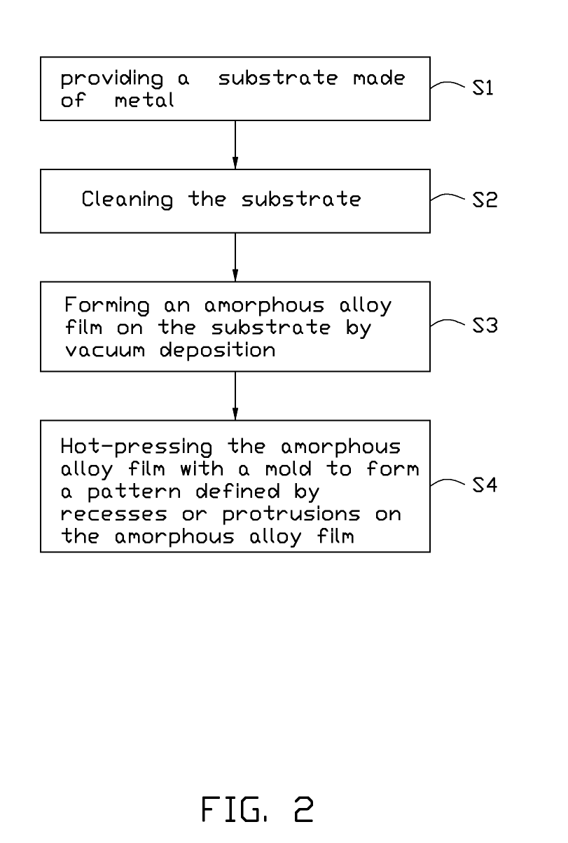

Referring to FIG. 2, an exemplary method for making the housing 10 may include steps S1 to S4.

In step S1, referring to FIG. 1, the substrate 12 is provided.

In step S2, the substrate 12 is cleaned in an ultrasonic cleaning device (not shown) filled with ethanol or acetone, to remove any impurities or grease.

In step S3, an amorphous alloy film 14 may be formed on the substrate 12 by vacuum deposition, using a metal alloy having a super-cooled liquid region of about 10 K or more as targets. The vacuum deposition may be a magnetron sputtering method or an arc ion plating method. In this exemplary embodiment, a magnetron sputtering method is used for forming the amorphous alloy film 14 as follows.

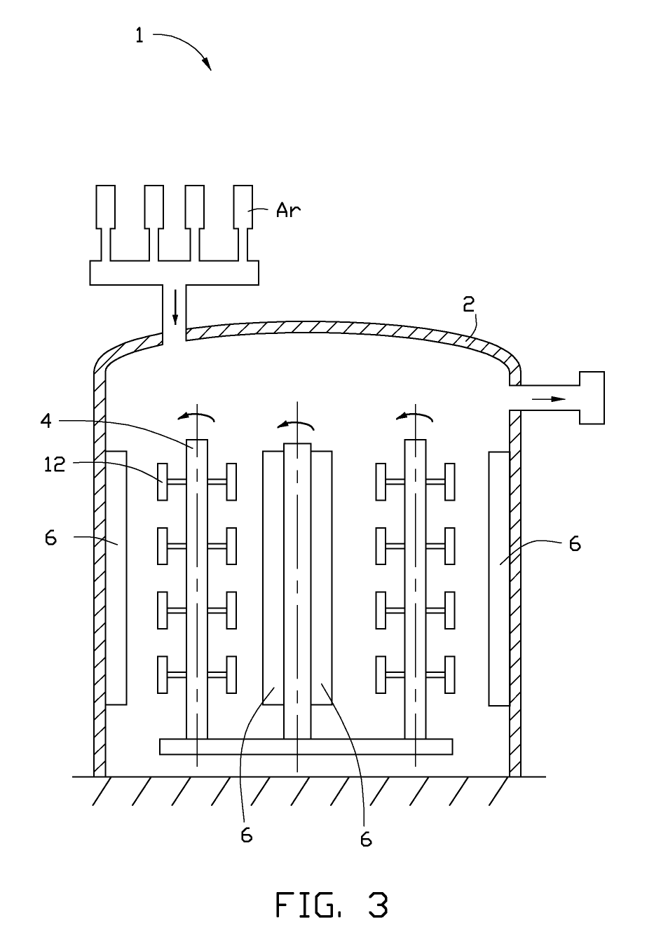

Referring to FIG. 3, the substrate 12 may be held on a rotating bracket 4 in a vacuum chamber 2 of a magnetron sputtering device 1. Metal alloy targets 6 having a super-cooled liquid region of about 10 K or more are fixed in the vacuum chamber 2. The metal alloy targets 6 may be made of a crystal alloy or amorphous alloy, either of which has a composition substantially same with the amorphous alloy film 14. In this embodiment, the metal alloy targets 6 are made of a crystal alloy. The speed of the rotating bracket 4 is between about 3 revolutions per minute (rpm) and about 12 rpm. The vacuum chamber 2 is evacuated to an internal pressure of about 6.0×10⁻³ Pa-8.0×10⁻³ Pa. The internal temperature of the vacuum chamber 2 may be of about 100° C.-180° C. Argon may be used as a sputtering gas and is fed into the vacuum chamber 2 at a flow rate of about 100 standard-state cubic centimeters per minute (sccm) to 300 sccm. A bias voltage of about −50 V to about −200 V is applied to the substrate 12. About 6 kW-12 kW of power at an intermediate frequency is then applied to the metal alloy targets 6, depositing the amorphous alloy film 14. Depositing of the amorphous alloy film 14 may take about 20 minutes (min)-40 min.

In step S4, the pattern 142 is then formed on the amorphous alloy film 14 by hot-pressing the amorphous alloy film 14 with a mold (not shown) having a surface defined with recesses or protrusions corresponding to the pattern 142. The substrate 12 with the amorphous alloy film 14 is heated to a temperature between the Tg and the Tx of the amorphous alloy film 14. The mold is then pressed on the amorphous alloy film 14 with a pressure of about 0.1 MPa-3 MPa, thus the pattern 142 is formed on the amorphous alloy film 14.

The housing 10 has an amorphous alloy film 14 formed on the substrate 12 by vacuum deposition using metal alloy targets having a large super-cooled liquid region. The amorphous alloy film 14 enhances the abrasion resistance and erosion resistance of the housing 10. The pattern 142 formed on the amorphous alloy film 14 provides a decorative appearance.

Specific examples of making the housing 10 are described as follows. The cleaning step in these specific examples may be substantially the same as described above so it is not described here again. The specific examples mainly emphasize the different process parameters of making the housing 10.

### Example 1

Magnetron sputtering to form the amorphous alloy film 14 on the substrate 12: the substrate 12 is made of stainless steel; the speed of the rotation of the bracket 4 is 3 rpm; the vacuum chamber 2 is evacuated to an internal pressure of about 8×10⁻³ Pa; the flow rate of argon is 150 sccm; the internal temperature of the vacuum chamber 2 is 120° C.; a bias voltage of −150 V is applied to the substrate 12; about 8 kW of power at an intermediate frequency is applied to the metal alloy targets 6; sputtering of the amorphous alloy film 14 takes about 25 min; the metal alloy targets 6 have a composition of Zr_{55%}Al_{20%}Co_{25%}. The amorphous alloy film 14 has a composition substantially same as that of the metal alloy targets 6.

Forming the pattern 142 on the amorphous alloy film 14: the substrate 12 with the amorphous alloy film 14 is heated to about 790 K; the mold used has a sandblasted surface; the mold is pressed on the amorphous alloy film 14 with a press of about 1.5 MPa. The pattern 142 has a profile corresponding to the sandblasted surface of the mold.

The housing 10 of example 1 has a pencil hardness of about 9H.

### Example 2

Magnetron sputtering to form the amorphous alloy film 14 on the substrate 12: the substrate 12 is made of aluminum alloy; the speed of the rotation of the bracket 4 is 3 rpm; the vacuum chamber 2 is evacuated to an internal pressure of about 8×10⁻³ Pa; the flow rate of argon is 150 sccm; the internal temperature of the vacuum chamber 2 is 120° C.; a bias voltage of −150 V is applied to the substrate 12; about 8 kW of power at an intermediate frequency is applied to the metal alloy targets 6; sputtering of the amorphous alloy film 14 takes about 25 min; the metal alloy targets 6 have a composition of Cu_{60%}Zr_{30%}Ti_{10%}. The amorphous alloy film 14 has a composition substantially same with that of the metal alloy targets 6.

Forming the pattern 142 on the amorphous alloy film 14: the substrate 12 with the amorphous alloy film 14 is heated to about 720 K; the mold used has a hairline finished surface; the mold is pressed on the amorphous alloy film 14 with a press of about 1.5 MPa. The pattern 142 has a profile corresponding to the hairline finished surface of the mold.

The housing 10 of example 1 has a pencil hardness of about 9H.

### Example 3

Magnetron sputtering to form the amorphous alloy film 14 on the substrate 12: the substrate 12 is made of titanium alloy; the speed of the rotation of the bracket 4 is 3 rpm; the vacuum chamber 2 is evacuated to an internal pressure of about 8×10⁻³ Pa; the flow rate of argon is 150 sccm; the internal temperature of the vacuum chamber 2 is 120° C.; a bias voltage of −150 V is applied to the substrate 12; about 8 kW of power at an intermediate frequency is applied to the metal alloy targets 6; sputtering of the amorphous alloy film 14 takes about 25 min; the metal alloy targets 6 have a composition of Ti_{50%}Cu_{32%}Ni_{15%}Sn_{3%}. The amorphous alloy film 14 has a composition substantially same with that of the metal alloy targets 6.

Forming the pattern 142 on the amorphous alloy film 14: the substrate 12 with the amorphous alloy film 14 is heated to about 710 K; the mold used has a surface defined a plurality of line-shaped recesses; the mold is pressed on the amorphous alloy film 14 with a press of about 2.5 MPa. The pattern 142 is defined by a plurality of line-shaped strips protruding the outer surface 140 of the amorphous alloy film 14.

The housing 10 of example 1 has a pencil hardness of about 9H.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

1. A housing for an electronic device, comprising:
a substrate made of metal; and
an amorphous alloy film formed on the substrate, the amorphous alloy film consisting of an amorphous alloy having a super-cooled liquid region of 10 K or more, the amorphous alloy film defining a pattern on an outer surface thereof, the pattern being defined by recesses or protrusions formed on the outer surface.

2. The housing as claimed in claim 1, wherein the amorphous alloy is one selected from the group consisting of zirconium-based amorphous alloy, copper-based amorphous alloy, and titanium-based amorphous alloy.

3. The housing as claimed in claim 2, wherein the zirconium-based amorphous alloy has a composition represented by the formula Zr_{54%-65%}Al_{10%-20%}Co_{18%-28%} or Zr_{50%-70%}Al_{18%-12%}Ni_{10%-20%}Cu_{10%-20%}, each of the subscript numerical values in the formulas indicates the weight percentage of a corresponding element.

4. The housing as claimed in claim 2, wherein the copper-based amorphous alloy has a composition represented by one of the formulas Cu_{50%-65%}Zr_{40%-45%}Al_{3%-5%}, Cu_{58%-65%}Zr_{28%-32%}Ti_{8%-12%}, and Cu_{58%-65%}Hf_{23%-27%}Ti_{8%-12%}, each of the subscript numerical values in the formulas indicates the weight percentage of a corresponding element.

5. The housing as claimed in claim 2, wherein the titanium-based amorphous alloy has a composition represented by the formula Ti_{50%}Ni_{15%-20%}Cu_{24%-33%}Sn_{2%-6%}, in which each of the subscript numerical values in the formula indicates the weight percentage of a corresponding element.

6. The housing as claimed in claim 1, wherein the amorphous alloy film has a thickness of about 0.5 μm-3 μm.

7. The housing as claimed in claim 1, wherein amorphous alloy film is formed by vacuum deposition.

8. The housing as claimed in claim 1, wherein the pattern is formed by hot-pressing the amorphous alloy film with a mold.

9. A method for making a coated article, comprising:
providing a substrate made of metal;
forming an amorphous alloy film on the substrate by vacuum deposition, using metal alloy targets having a super-cooled liquid region of about 10 K or more; and
forming a pattern on the amorphous alloy film by hot-pressing the amorphous alloy film with a mold having a surface defined with recesses or protrusions corresponding to the pattern.

10. The method as claimed in claim 9, wherein the amorphous alloy film is formed by magnetron sputtering.

11. The method as claimed in claim 10, wherein magnetron sputtering of the amorphous alloy film uses argon at a flow rate of about 100 sccm-300 sccm as a sputtering gas; applies a power of about 6 kW-12 kW to the nickel-chromium alloy targets; applies a bias voltage of about −50 V to about −200 V to the substrate; magnetron sputtering of the bonding layer is conducted at a temperature of about 100° C.-180° C. and takes about 20 min-40 min.

12. The method as claimed in claim 11, wherein during magnetron sputtering of the amorphous alloy film, the substrate is held on a rotating brocket in vacuum chamber of a magnetron sputtering machine, the speed of the rotating brocket is about 3 rpm-12 rpm, the vacuum chamber is evacuated to an internal pressure of about 6×10⁻³ Pa-8×10⁻³ Pa.

13. The method as claimed in claim 9, wherein the hot-pressing process is carried out by heating the substrate with the amorphous to a temperature between the glass transition temperature and the crystallization temperature of the amorphous alloy film, and then hot-pressing the amorphous alloy film with the mold.

14. The method as claimed in claim 9, further comprising a step of cleaning the substrate in an ultrasonic cleaning device filled with ethanol or acetone, before the step of forming the amorphous alloy film.
